(19) United States
(12) Patent Application Publication
(10) Pub. No.: US 2014/0179035 A1
(43) Pub. Date: Jun. 26, 2014

(54) METHOD FOR DISPENSING GLUE ON LED CHIP

(71) Applicant: Hon Hai Precision Industry Co., Ltd., New Taipei (TW)

(72) Inventor: CHIH-CHEN LAI, New Taipei (TW)

(73) Assignee: Hon Hai Precision Industry Co., Ltd., New Taipei (TW)

(21) Appl. No.: 14/022,236

(22) Filed: Sep. 10, 2013

(30) Foreign Application Priority Data
Dec. 26, 2012 (TW) 101150293

(51) Int. Cl. H01L 33/52

(52) U.S. Cl. CPC H01L 33/52
USPC 438/26

(57) ABSTRACT

A method for dispensing glue on an LED chip includes following steps: providing a glue dispensing device which includes a syringe, a needle head communicating with the syringe, and a valve mounted on the needle head for controlling flowing of content in the syringe out of the syringe, wherein the valve has an aperture, and a diameter of the aperture is adjustable; providing glue and injecting the glue into the syringe; providing an LED chip which is mounted a circuit board and orientating the needle head of the glue dispensing device towards the LED chip, wherein the needle head is spaced from the LED chip, and the diameter of the aperture of the valve is adjusted to a predetermined size; squeezing the glue out of the syringe under a predetermined pressure and a predetermined time, wherein the glue dispensed on the LED chip forms an encapsulation structure.

### BACKGROUND

1. Technical Field

The disclosure relates a method for dispensing glue on an LED (light emitting diode) chip, and particularly to a method for dispensing glue on an LED chip which facilitates forming encapsulation structures with different shapes and sizes.

2. Discussion of Related Art

Light emitting diodes' (LEDs) many advantages, such as high luminosity, low operational voltage, low power consumption, compatibility with integrated circuits, easy driving, long term reliability, and environmental friendliness have promoted their wide use as a lighting source.

An encapsulation structure is commonly formed by dispensing glue on an LED chip using a glue dispensing device. A conventional glue dispensing device includes a syringe receiving the glue therein, and a needle head communicating with the syringe. The needle head of the glue dispensing device is orientated towards the LED chip. The glue is then squeezed out of the syringe via the needle head under a predetermined pressure and a predetermined time to flow to and cover the LED chip. Although the amount of the glue dispensed on the LED chip can be controlled by controlling the pressure and the time of squeezing the glue, the shape and the size of the encapsulation structure can not be easily changed/controlled to meet different requirements.

Therefore, what is needed is a method for dispensing glue on an LED chip which can overcome the described limitations.

### BRIEF DESCRIPTION OF THE DRAWINGS

Many aspects of the disclosure can be better understood with reference to the following drawing. The components in the drawing are not necessarily drawn to scale, the emphasis instead being placed upon clearly illustrating the principles of the present method for dispensing glue to an LED chip. Moreover, in the drawing, like reference numerals designate corresponding parts throughout the whole view.

FIG. 1 is a schematic view of a method for dispensing glue on an LED chip, in accordance with a first embodiment of the present disclosure.

FIG. 2 is a schematic view of a method for dispensing glue on an LED chip, in accordance with a second embodiment of the present disclosure.

FIG. 3 is a schematic view of a method for dispensing glue on an LED chip, in accordance with a third embodiment of the present disclosure.

FIG. 4 is a schematic view of a method for dispensing glue on an LED chip, in accordance with a fourth embodiment of the present disclosure.

### DETAILED DESCRIPTION OF EMBODIMENTS

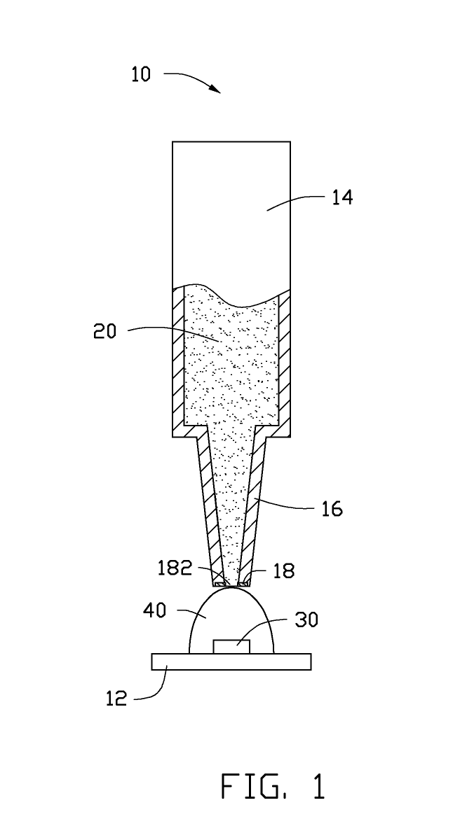

Referring to FIG. 1, a method for dispensing glue on an LED chip in accordance with a first embodiment is provided, which includes the following steps.

The first step is to provide a glue dispensing device 10. The glue dispensing device 10 includes a syringe 14, a needle head 16 communicating with the syringe 14, and a valve 18 mounted on a distal end of the needle head 16 away from the syringe 14.

The second step is to provide glue 20 and inject the glue 20 into the syringe 14 slowly along an inner wall of the syringe 14. The valve 18 has an aperture 182. A diameter of the aperture 182 is adjustable, so that an amount of the glue 20 flowing out the valve 18 per unit time can be controlled precisely by controlling the opening degree of the aperture 182 of the valve 18. The material of the glue 20 is silicone, epoxy resin, or a mixture of silicone and epoxy resin.

The third step is to provide an LED chip 30 which is mounted on a circuit board 12 and orientate the needle head 16 of the glue dispensing device 10 towards a center of the LED chip 30. The needle head 16 is located over and spaced from the LED chip 30 with a certain distance (2 millimeters, for instance). The diameter of the aperture 182 of the valve 18 is adjusted to a predetermined size.

The fourth step is to squeeze the glue 20 out of the syringe 14 under a predetermined pressure P1 and a predetermined time T1 (for instance, the predetermined pressure P1 is 0.1 mpa, the predetermined time T1 is 0.4 second). Simultaneously, the needle head 16 is moved upwardly and slowly. The diameter of the aperture 182 of the valve 18 is kept unchanged during the process of squeezing the glue 20. The glue 20 dispensed on the LED chip 30 forms an encapsulation structure 40 when solidified. The encapsulation structure 40 has a curved top face and a planar bottom face.

The fifth step is to clean away the remaining glue 20 on the needle head 16 using a sponge.

When the above method is used for mass-production of the encapsulation structure 40, performing the above steps repeatedly.

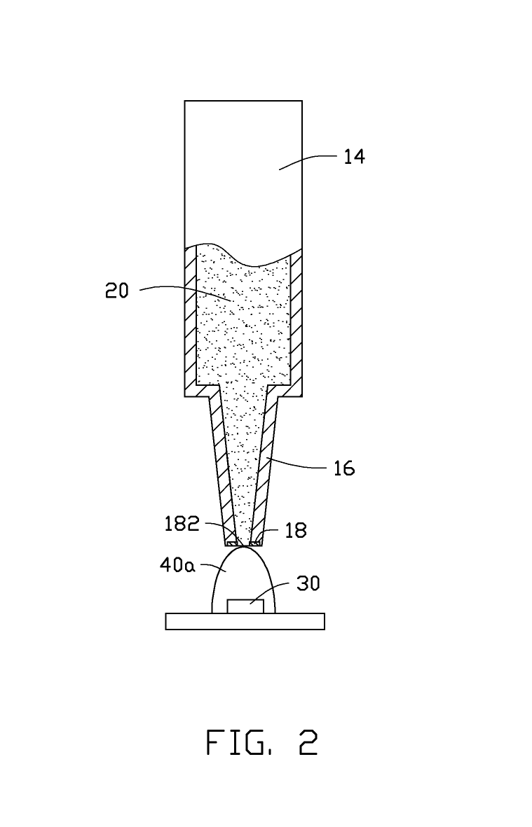

Referring to FIG. 2, a method for dispensing glue on an LED chip in accordance with a second embodiment is provided, which includes a first step, a second step, a third step, a fourth step and a fifth step. The first step, the second step, the third step and the fifth step of the method in the second embodiment are identical to the first step, the second step, the third step and the fifth step of the method in the first embodiment, respectively. The difference between the method in the second embodiment and the method in the first embodiment is in the fourth step.

The fourth step in the second embodiment is to squeeze the glue 20 out of the syringe 14 under a predetermined pressure P2 and a predetermined time T2. Simultaneously, the needle head 16 is moved upwardly and slowly. The diameter of the aperture 182 of the valve 18 is gradually decreased during the process of squeezing the glue 20. The glue 20 dispensed on the LED chip 30 forms an encapsulation structure 40a. The pressure P2 and the time T2 are equal to the pressure P1 and the time T1 in the fourth step of the first embodiment, respectively. The encapsulation structure 40a has a curved top face and a planar bottom face. The top face of the encapsulation structure 40a has a curvature larger than that of the top face of the encapsulation structure 40 in the first embodiment. The bottom face of the encapsulation structure 40a has a diameter smaller than that of the bottom face of the encapsulation structure 40 in the first embodiment.

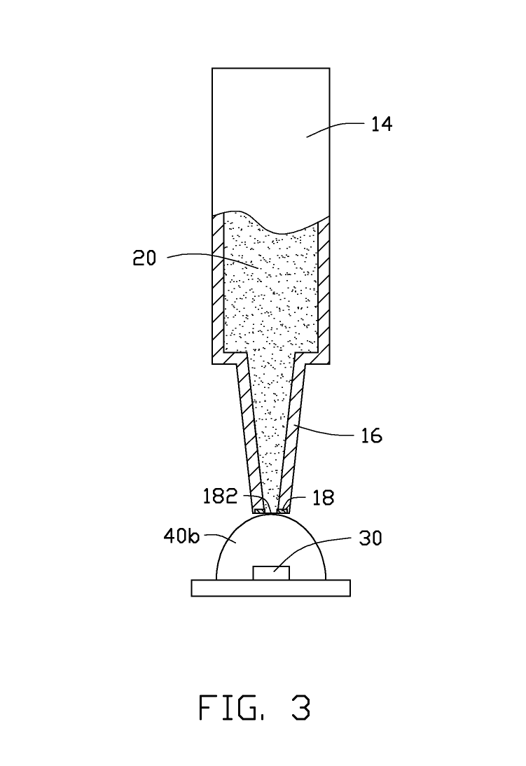

Referring to FIG. 3, a method for dispensing glue on an LED chip in accordance with a third embodiment is provided, which includes a first step, a second step, a third step, a fourth step and a fifth step. The first step, the second step, the third step and the fifth step of the method in the third embodiment are identical to the first step, the second step, the third step and the fifth step of the method in the first embodiment, respectively. The difference between the method in the third embodiment and the method in the first embodiment is in the fourth step.

The fourth step in the third embodiment is to squeeze the glue 20 out of the syringe 14 under a predetermined pressure P3 and a predetermined time T3. Simultaneously, the needle head 16 is moved upwardly and slowly. The diameter of the aperture 182 of the valve 18 is kept unchanged during the process of squeezing the glue 20. The glue 20 dispensed on the LED chip 30 forms an encapsulation structure 40b. The pressure P3 is equal to the pressure P1 in the fourth step of the first embodiment. The time T3 is larger than the time T1 in the fourth step of the first embodiment. The encapsulation structure 40b has a curved top face and a planar bottom face. The top face of the encapsulation structure 40b has a curvature smaller than that of the top face of the encapsulation structure 40 in the first embodiment. The bottom face of the encapsulation structure 40b has a diameter larger than that of the bottom face of the encapsulation structure 40 in the first embodiment.

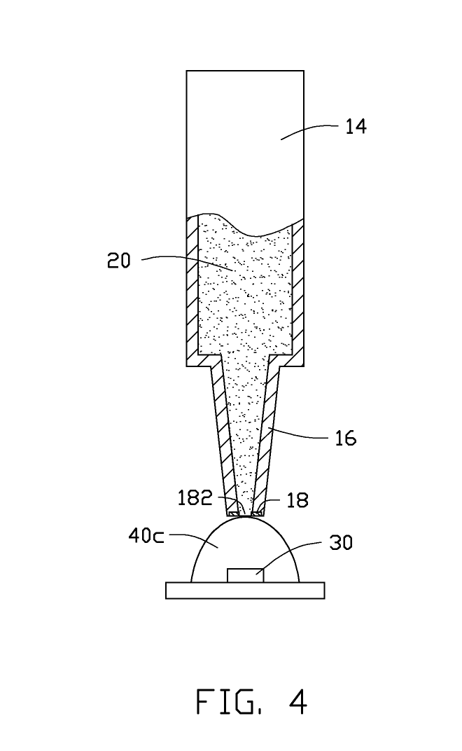

Referring to FIG. 4, a method for dispensing glue on an LED chip in accordance with a fourth embodiment is provided, which includes a first step, a second step, a third step, a fourth step and a fifth step. The first step, the second step, the third step and the fifth step of the method in the fourth embodiment are identical to the first step, the second step, the third step and the fifth step of the method in the first embodiment, respectively. The distinction among the method in the fourth embodiment, the method in the first embodiment, and the method in the third embodiment is the fourth step.

The fourth step in the fourth embodiment is to squeeze the glue 20 out of the syringe 14 under a predetermined pressure P4 and a predetermined time T4. Simultaneously, the needle head 16 is moved upwardly and slowly. The diameter of the aperture 182 of the valve 18 is gradually decreased during the process of squeezing the glue 20. The glue 20 dispensed on the LED chip 30 forms an encapsulation structure 40c. The pressure P4 is equal to the pressure P1 in the fourth step of the first embodiment. The time T4 is larger than the time T1 in the fourth step of the first embodiment, and is equal to the time T3 in the fourth step of the third embodiment. The encapsulation structure 40c has a curved top face and a planar bottom face. The top face of the encapsulation structure 40c has a curvature smaller than the curvature of the top face of the encapsulation structure 40 in the first embodiment, but larger than the curvature of the top face of the encapsulation structure 40b in the third embodiment. The bottom face of the encapsulation structure 40c has a diameter larger than the diameter of the bottom face of the encapsulation structure 40 in the first embodiment, but smaller than the diameter of the bottom face of the encapsulation structure 40b in the third embodiment.

In other embodiments of the present disclosure, the diameter of the aperture 182 of the valve 18 can also be adjusted to be gradually increased during the process of squeezing the glue 20, so that the top face of the encapsulation structure has a diameter larger than the diameter of the bottom face of the encapsulation structure. The pressure of squeezing the glue 20 can be gradually increased or gradually decreased, to meet requirements of forming the encapsulation structures with different shapes and sizes.

According to the present disclosure, since the valve 18 with the aperture 182 is connected on the distal end of the needle head 16 of the glue dispensing device 10, and the diameter of the aperture 182 is adjustable according to requirements, the amount of the glue 20 dispensed per unit time can be controlled precisely. In addition, the setting of the diameter of the aperture 182 of the valve 18 cooperates with the setting of the pressure and the time of squeezing the glue 20, so that the encapsulation structures with different shapes and sizes can be conveniently formed.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A method for dispensing glue on an LED (light emitting diode) chip, comprising following steps:
providing a glue dispensing device, the glue dispensing device comprising a syringe, a needle head communicating with the syringe, and a valve connected on the needle head, the valve having an aperture, a diameter of the aperture being adjustable;
providing glue and injecting the glue into the syringe;
providing an LED chip which is mounted on a substrate and orientating the needle head of the glue dispensing device towards the LED chip, the needle head being spaced from the LED chip, the diameter of the aperture of the valve being adjusted to a predetermined size; and
squeezing the glue out of the syringe through the valve under a predetermined pressure and a predetermined time to the LED chip, the glue dispensed on the LED chip forming an encapsulation structure, the encapsulation structure having a curved top face and a planar bottom face.

2. The method of claim 1, further comprising a step of cleaning away glue remained on the needle head by using a sponge after the encapsulation is formed.

3. The method of claim 1, wherein the needle head is moved upwardly and slowly during the process of squeezing the glue.

4. The method of claim 1, wherein the pressure and the time are kept unchanged during the process of squeezing the glue, and the diameter of the aperture of the valve is gradually decreased during the process of squeezing the glue.

5. The method of claim 1, wherein the pressure and the diameter of the aperture of the valve are kept unchanged during the process of squeezing the glue, and the time is increased during the process of squeezing the glue.

6. The method of claim 1, wherein during the process of squeezing the glue, the pressure is kept unchanged, the time is increased, and the diameter of the aperture of the valve is gradually decreased.

7. The method of claim 1, wherein the diameter of the aperture of the valve is gradually increased during the process of squeezing the glue.

8. The method of claim 1, wherein the pressure of squeezing the glue is gradually increased during the process of squeezing the glue.

9. The method of claim 1, wherein the pressure of squeezing the glue is gradually decreased during the process of squeezing the glue.

10. The method of claim 1, wherein the material of the glue is silicone, epoxy resin, or a mixture of silicone and epoxy resin.
